(19) United States
(12) Patent Application Publication
(10) Pub. No.: US 2020/0007154 A1
(43) Pub. Date: Jan. 2, 2020

(54) METHOD AND DEVICE FOR THE LOSSLESS COMPRESSION OF A DATA STREAM

(71) Applicant: Siemens Aktiengesellschaft, München (DE)

(72) Inventors: Martin Schneider, München (DE); Gerd Völksen, München (DE)

(21) Appl. No.: 16/482,286

(22) PCT Filed: Dec. 13, 2017
(86) PCT No.: PCT/EP2017/082521

§ 371 Date: Jul. 31, 2019

(30) Foreign Application Priority Data
Jan. 31, 2017 (DE) 10 2017 201 506.3

(51) Int. Cl. H03M 7/30; G06F 16/25

(52) U.S. Cl. CPC H03M 7/3088; G06F 16/258; H03M 7/707; H03M 7/3091

(57) ABSTRACT

Provided is a method and a device for the lossless compression of a data stream which includes a sequence of structured data objects which have a list of properties which each contain a key value pair, the method having the following steps: dividing the structured data objects of the data stream into a constant data object portion which has key value pairs with constant values and into variable data object portions which have key value pairs with variable values; transmitting the constant data object portion of the structured data objects once to a receiver; and transmitting the variable data object portions of the divided data objects of the data stream to the receiver.

### CROSS-REFERENCE TO RELATED APPLICATIONS

This application claims priority to PCT Application No. PCT/EP2017/082521, having a filing date of Dec. 13, 2017, which is based on German Application No. 10 2017 201 506.3, having a filing date of Jan. 31, 2017, the entire contents both of which are hereby incorporated by reference.

### FIELD OF TECHNOLOGY

The following relates to a method and a device for the lossless compression of a data stream, in particular of an event data stream.

### BACKGROUND

In the digitization of systems, for example industrial installations or distributed systems based on the Internet, these systems are equipped with sensors and data networks in order at any time to detect the states of the entire system and of the subsystems thereof or of individual components within the system and, if appropriate, to derive necessary measures therefrom. These measures include control interventions, optimization processes or preventive activities. Furthermore, the data obtained may be stored in order to be able to carry out an analysis of the behavior of the system or installation and to be able to demonstrate processes within the system if necessary.

If a large number of sensors are installed in an installation or a system and these sensors each generate sensor data with a high frequency, the transmission and processing of the generated sensor data prove to be difficult. By way of example, if 25 000 sensors generate data or data packets having a data volume of 100 bytes with a clock cycle of tenths of a second, then it is necessary to transmit, to process and, if appropriate, also to store approximately 2 terabytes per day. As the complexity of the systems or installations increases, the amounts of data will rise further.

In conventional systems various solution approaches exist for reducing the data transport volume and the processing overhead for processing the data.

A decentralization of the data processing of sensor data makes it possible for the data processing overhead to be distributed among different components or units within the system. That has the consequence that a bottleneck in the data transport in the case of a central data processing unit disappears. Possible components of the system that may be used include network nodes, control elements and other hardware units which are connected to the data network of the system and have a sufficiently free data memory and a suitable processor for data processing. Each of the components of the system can be assigned rules or algorithms that specify how the signals or sensor data are to be processed.

A so-called publish/subscribe approach involves transporting sensor data from their producers or data sources only to those consumers that actually require these data. As a result, it is possible for the communication network between the components not to be completely flooded with all of the data, but rather for the data transport within the system to be reduced to a minimum in the sense of a multicast instead of a broadcast. In this conventional solution approach, therefore, the data that are not subscribed to are not distributed within the system.

A further conventional solution approach consists in distributing the sensor data processing among so-called event processing units (EPUs in the data network, thus breaking up central data processing of the sensor data or sensor signals. The event processing units can be distributed among the various network nodes or control components within the system or network. In this case, the functions, i.e. the rules and algorithms, are normally distributed in such a way that the distance between the signal producers, i.e. the sensors, and the signal consumers, i.e. the event processing units with the data processing rules integrated therein, is minimized. In this case, the distance can be measured using an appropriate metric, for example by means of a so-called hop count or a data transport speed.

By means of corresponding rules and algorithms, the event processing units can filter the data streams, for example with respect to time, value or value deviation, aggregate the data streams, for example by calculating a mean, a standard deviation or a median, or correlate the data streams, for example by extracting from different types of signals higher-value, content-richer information, namely a so-called event. Each network node or each control component within the system can therefore appear both as a consumer and as a producer of events.

What these conventional solution approaches have in common is that the data traffic is reduced to an extent such that only the respective segments of the network or system in which there are actually subscribing consumers and by means of which the data processing can be carried out more rapidly are loaded with data traffic. These solution approaches are utilized in the context of so-called distributed complex event processing.

Various technological approaches may be pursued for the processing of data, in particular so-called event data. In the case of so-called single event processing, each event generates a specific reaction, wherein decision tables can be used, for example. So-called event stream processing involves processing one or more synchronized sequences of events of the same type which originate from the same data source, for example sensor or EPU, by a specific action being generated from predefined sequence patterns of the event values. Automata can be used in this case, for example.

So-called complex event processing involves processing a very high, heterogeneous non-synchronized sequence of events from different data sources by recognizing predefined event patterns and generating or deriving specific actions therefrom. Pattern recognition can be used in this case.

In the case of a publish/subscribe approach, at each event processing unit (EPU) only those events appear which are actually subscribed to there and can accordingly be processed.

The conventional approaches for reducing the data transport volume and the data processing overhead of data encounter their limits, however, when there are large amounts of data.

### SUMMARY

An aspect relates to a method and a device which further reduce the overhead for data transmission and data processing.

The embodiments of the invention accordingly provide a method for the lossless compression of a data stream comprising a sequence of structured data objects having a list of properties which each contain a key-value pair, wherein the method comprises the following steps:

decomposing the structured data objects of the data stream into a constant data object portion, which has key-value pairs having constant values, and into variable data object portions, which have key-value pairs having variable values;
transmitting the constant data object portion of the structured data objects once to a receiver; and
transmitting the variable data object portions of the decomposed data objects of the data stream to the receiver.

In one possible embodiment of the method according to the embodiments of the invention, the structured data objects of the data stream have JavaScript Object Notation, JSON, data objects.

In one possible embodiment of the method according to the embodiments of the invention, each key-value pair has a key formed by a character string.

In an alternative embodiment of the method according to the embodiments of the invention, each key-value pair has a key formed by a number.

In a further possible embodiment of the method according to the embodiments of the invention, the key-value pair has a value formed by a data object, an array, a character string, a numerical value or a logical value.

In a further possible embodiment of the method according to the embodiments of the invention, the variable data object portion of the decomposed structured data object of the data stream has an array, the components of which are key-value pairs that are streamed asynchronously to the receiver.

In a further possible embodiment of the method according to the embodiments of the invention, the variable data object portions of a data stream each contain a unique identification identifier for identifying their association with the data stream.

In a further possible embodiment of the method according to the embodiments of the invention, changes in the variable data object portion of the structured data object of the data stream relative to a reference data object are determined and transmitted to the receiver.

In a further possible embodiment of the method according to the embodiments of the invention, the reference data object is formed by a structured data object of the data stream having a predetermined endurance.

In a further possible embodiment of the method according to the embodiments of the invention, the reference data object of the data stream is identified as such and is transmitted to the receiver.

In a further possible embodiment of the method according to the embodiments of the invention, the endurance of the reference data object is defined by a number of transmission cycles or a validity period.

In a further possible embodiment of the method according to the embodiments of the invention, decomposing the structured data objects of the data stream is carried out at the run time during the transmission of the data stream to the receiver.

In a further possible embodiment of the method according to the embodiments of the invention, on the part of the receiver, the structured data objects of the data stream are reconstructed for further data processing on the basis of the obtained constant data object portion and the received variable data object portions.

In a further possible embodiment of the method according to the embodiments of the invention, on the part of the receiver, the structured data objects of the data stream are reconstructed for further data processing on the basis of the buffer-stored reference data objects and the received changes in the variable data object portions.

In a further possible embodiment of the method according to the embodiments of the invention, the data stream is an event data stream, in particular a sensor data stream.

Furthermore, in accordance with a further aspect, the embodiments of the invention provide a compression device for the lossless compression of a data stream having the features specified in patent claim 15.

The embodiments of the invention accordingly provide a compression device for the lossless compression of a data stream comprising a sequence of structured data objects having a list of properties which each consists of a key-value pair, wherein the device comprises:

a data decomposition unit (DZE) suitable for decomposing the structured data objects of the data stream into a constant data object portion, which has key-value pairs having constant values, and into variable data object portions, which have key-value pairs having variable values; and
a data transmission unit (DUE), which transmits once the constant data object portion and separately the variable data object portions of the decomposed data objects to a receiver.

### BRIEF DESCRIPTION

Some of the embodiments will be described in detail, with reference to the following figures, wherein like designations denote like members, wherein:

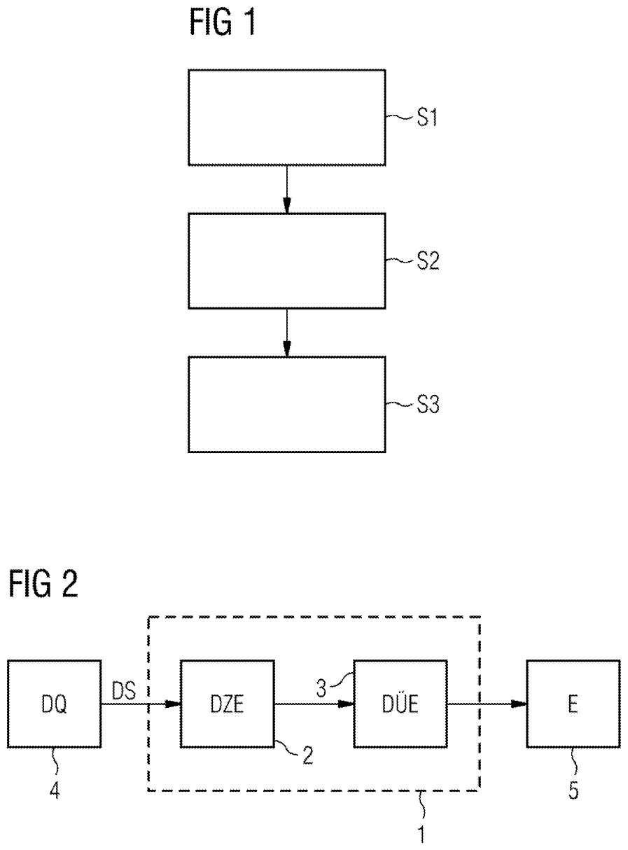

FIG. 1 shows a flow diagram for illustrating one possible embodiment of the method according to the embodiments of the invention for the lossless compression of a data stream;

FIG. 2 shows a block diagram for illustrating one possible embodiment of a compression device according to embodiments of the invention for the lossless compression of a data stream.

### DETAILED DESCRIPTION

As can be discerned in FIG. 1, a method according to the embodiments of the invention for the lossless compression of a data stream, in the exemplary embodiment illustrated, substantially comprises three steps.

The data stream DS consists of a sequence of structured data objects. These data objects each have a list of so-called properties which each contain a key-value pair.

A first step S1 involves decomposing the structured data objects of the data stream into a constant data object portion and into variable data object portions. In this case, the constant data object portion has key-value pairs having constant values. The variable data object portions have key-value pairs having variable values.

Afterward, step S2 involves transmitting the formed constant data object portion of the structured data objects once to a receiver.

A further step S3 involves transmitting the variable data object portions of the decomposed data objects of the data stream to the receiver E.

In this exemplary embodiment of the method according to the embodiments of the invention as illustrated in FIG. 1, firstly the constant data object portion is transmitted in step S2 and afterward the variable data object portions of the decomposed data object are transmitted in step S3. In one possible embodiment, the data object portions are transmitted from a transmitter to the receiver via a data transmission medium. This can be a data network, for example, in which network nodes are interlinked via lines. In this case, the data transmission of the constant and variable data object portions is effected via data lines. Alternatively, the data transmission of the constant and variable data objects can also be effected wirelessly via an air interface.

FIG. 2 shows a block diagram of one possible embodiment of a compression device 1 according to the embodiments of the invention for the lossless compression of a data stream DS comprising a sequence of structured data objects DO. Each of said data objects DO has a list of properties which each consist of a key-value pair. The compression device 1 illustrated in FIG. 2 comprises a data decomposition unit 2 and a data transmission unit 3. The data decomposition unit 2 is suitable for decomposing the structured data objects of the received data stream into a constant data object portion, which has key-value pairs having constant values, and into variable data object portions, which have key-value pairs having variable values. The compression device 1 contains a data transmission unit 3, which transmits once the constant data object portion generated by the data decomposition unit 2 and separately the variable data object portions of the decomposed data objects, said variable data object portions being generated by the data decomposition unit 2, to at least one receiver.

As illustrated in FIG. 2, the data decomposition unit 2 of the compression device 1 receives from a data source (DQ) 4 at least one data stream (DS) comprising a sequence of structured data objects DO. The structured data objects of the data stream DS are decomposed by the data decomposition unit 2 of the compression device 1, specifically into a constant data object portion and into variable data object portions. Afterward, the data transmission unit 3 of the compression device 1 transmits the constant data object portion once to a receiver 5. Furthermore, afterward, the variable data object portions of the decomposed data objects of the data stream, said variable data object portions being generated by the data decomposition unit 2, are transmitted separately to the receiver 5 by the data transmission unit 3. The receiver 5 preferably has a data reconstruction unit for reconstructing the structured data objects DO from the constant data object portion and the received variable data object portions.

In one possible embodiment, the structured data objects DO of the data stream DS have JavaScript Object Notation, JSON, data objects. The JSON data object forms a data format suitable for the transmission and storage of structured data. With a JSON data format, data can be nested. In the case of JSON, a null value, a Boolean value, a number, a character string, an array and an object are provided as data types. In this case, an object contains a list of properties. However, objects without properties, so-called empty objects, are also permissible. A property of the object consists of a key and a value, wherein each key is permitted to be contained in an object only once. In one preferred embodiment, the key is formed by a character string. The value of the key-value pair can be formed by an object, by an array, by a character string, by a number or by a Boolean expression.

In one possible embodiment of the method according to the embodiments of the invention, each key-value pair of the structured data object DO has a key formed by a character string or a number. Furthermore, in one possible embodiment, the key-value pair of the JSON data object has a value formed by a data object, an array, a character string, a numerical value or a logical value.

In one possible embodiment, the variable data object portions of the structured data objects of the data stream DS, said structured data objects being decomposed by the data decomposition unit 2, can have an array, the components of which are key-value pairs that are streamed asynchronously by the data transmission unit 3 through the receiver 5.

In a further possible embodiment of the method according to the embodiments of the invention, the variable data object portions of a data stream each contain a unique identification identifier for identifying their association with the respective data stream DS.

In one possible embodiment, changes in the variable data object portion of the structured data object of the data stream DS relative to a reference data object are determined and transmitted to the receiver 5. In this case, the reference data object can be formed by a structured data object of the data stream having a predetermined endurance. In one possible embodiment, the reference data object is firstly transmitted to the receiver 5 and buffer-stored there for further use. The reference data object is preferably identified as such and is transmitted to the receiver 5 by the data transmission unit 3 of the compression device 1 and is buffer-stored in the receiver.

In a further possible embodiment of the method according to the embodiments of the invention, the endurance of the reference data object is defined by a number of transmission cycles. In a further possible embodiment, the endurance of the reference data object is defined by a specific validity period and/or expiry time.

In one possible embodiment, decomposing the structured data object at the data decomposition unit 2 is carried out at the run time during the transmission of the data stream DS to the receiver 5. On the part of the receiver 5, the structured data objects DO of the original data stream DS can be reconstructed for further data processing on the basis of the obtained constant data object portion and the received variable data object portions. In one possible embodiment, on the part of the receiver 5, the structured data objects DO of the data stream DS are reconstructed for further data processing on the basis of the buffer-stored reference data objects and received changes in the variable data object portions. The data stream received from the data source 4 is preferably an event stream. In one possible embodiment, the data source 4 is a sensor that generates sensor data which are transmitted as a sensor data stream from the data source 4 to the compression device 1.

The compression of the data streams DS by the compression device 1 makes it possible to lower the data rate of the data transmission. A data stream DS, which can be a data stream of event data, comprises a sequence of structured data objects. In one possible embodiment, a single data stream DS is generated by a data source 4, for example a sensor or some other unit of the system. Said data stream can consist for example of a sequence of data triples comprising for example a sensor ID of the sensor 4, a time stamp and a sensor value.

By way of example, a structured data object of the data stream DS in JSON notation can be represented as follows:

```
{ “SensorID” : “ABC1234”,
  “Timestamp” : “2016-06-10T13:47:26.0123+02:00”,
  “Sensorvalue” : 987.654 }.
```

In one possible embodiment, firstly an event data object is generated from a generated sensor signal or sensor data sequence. An event constitutes a structured data configuration comprising further information over and above the pure sensor data. By way of example, an event data object containing sensor data of a heat sensor can specify the dimension or unit of the sensor data, that is to say for example ° C. or ° F. or ° K, depending on how the relevant sensor or the data source 4 is designed or configured. In association with a published/subscriber approach, a consumer or a data processing unit can subscribe to an event that supplies a temperature value from a specific location, wherein it is of secondary importance, for example, whether the sensor value originates from a heat sensor or a thermal imaging camera. In the case of higher-level events generated by correlation of different data, a numerical value may sometimes be totally absent. By way of example, a fire alarm event can be derived from the sensor data of a smoke detector and from the sensor data of a heat sensor, wherein the two sensors, i.e. the smoke detector and the heat sensor, monitor the same spatial region and their sensor data must originate from a given time window.

The compression device 1 according to the embodiments of the invention allows a lossless compression of the data stream originating from the data source 4. This means that no loss of information is brought about by the method according to the embodiments of the invention and the compression device 1 according to the embodiments of the invention. Precisely if the value of an event is not of a numerical nature, but rather constitutes a complex data configuration, a loss of information should be avoided. This holds true, in particular, if the source of the event stream is already filtered with respect to a time or value criterion. Each event that is transmitted or emitted by a data source or event source 4 has to be able to be completely reconstructed at the associated receivers 5.

A discrete sequence of sensor data or events originating from the same data source 4 can be transmitted as a data stream or a so-called stream. One example of a sequence of primitive events or sensor data reads as follows:

$${\{}^{″} Sensor {data}^{″} : {{\{}^{″} {SensorID}^{″} : string ,}^{″} {Timestamp}^{″} : string1 , {}^{″} {Sensorvalue}^{″} : number1 \} \} \\ {\{}^{″} Sensor {data}^{″} : {{\{}^{″} {SensorID}^{″} : string ,}^{″} {Timestamp}^{″} : string2 , {}^{″} {Sensorvalue}^{″} : number2 \} \}$$

$$…$$

$${\{}^{″} Sensor {data}^{″} : {\{}^{″} {SensorID}^{″} : string , {}^{″} {Timestamp}^{″} : stringN {,}^{″} {Sensorvalue}^{″} : numberN \} \}$$

This sequence of data objects DO can be represented as a stream as follows:

```
{“Sensor data Stream” :
      { “SensorID” : string , [
    { “Timestamp” : string1, “Sensorvalue” : number1 } ,
    { “Timestamp” : string2, “Sensorvalue” : number2 } ,
    ...,
    { “Timestamp” : stringN, “Sensorvalue” : numberN } ] } }
```

In this case, the constant portion of the sequence of sensor data objects, namely the sensor IDs, is withdrawn or bracketed out from the sequence.

The variable portions of the sensor data sequence, namely the time stamps and values, are combined into a JSON array in the example illustrated. The streaming mechanism ensures that the data are transmitted asynchronously and continuously to the receiver 5, that is to say that the data objects DO of the data stream DS that transmits the array can already be read at the receiver 5 while the data transmission unit of the compression device 1 is still generating further data objects and writing them into the array or the stream.

In the case of discrete event data and a portion that is variable in a defined manner, the streaming can generally be carried out by bracketing out the constant portions of the structured data object as follows:

$${\{}^{″} Event {data}^{″} \text{:} \{ {K}_{1} \text{:} {C}_{1} {K}_{2} \text{:} {C}_{2} , … , {K}_{N} \text{:} {C}_{N} , {K}_{N + 1} \text{:} {V}_{N + {1}_{1}} , {K}_{N + 2} {V}_{N + {2}_{1}} , … , {K}_{N + M} \text{:} {V}_{N + {M}_{1}} \} \} \\ {\{}^{″} Event {data}^{″} \text{:} \{ {K}_{1} \text{:} {C}_{1} {K}_{2} \text{:} {C}_{2} , … , {K}_{N} \text{:} {C}_{N} , {K}_{N + 1} \text{:} {V}_{N + {1}_{2}} , {K}_{N + 2} \text{:} {V}_{N + {2}_{2}} , … , {K}_{N + M} \text{:} {V}_{N + {M}_{2}} \} \} \\ … \\ {\{}^{″} Event {data}^{″} \text{:} \{ {K}_{1} \text{:} {C}_{1} {K}_{2} \text{:} {C}_{2} , … , {K}_{N} \text{:} {C}_{N} , {K}_{N + 1} \text{:} {V}_{N + {1}_{L}} , {K}_{N + 2} \text{:} {V}_{N + {2}_{L}} , … , {K}_{N + M} \text{:} {V}_{N + {M}_{L}} \} \}$$

In this case, Kₛ denotes the keys of the key-value pairs, and Cₛ denotes the constant values. Vₛ denotes variable values. The sequence of data objects DO represented above can be summarized as follows:

$${\{}^{″} Event data {stream}^{″} \text{:} \{ {K}_{1} \text{:} {C}_{1} , {K}_{2} \text{:} {C}_{2} , … , {K}_{N} \text{:} {C}_{N} , [ \begin{matrix}\{ {K}_{N + 1} \text{:} {V}_{N + {1}_{1}} , {K}_{N + 2} \text{:} {V}_{N + {2}_{1}} , … , {K}_{N + M} \text{:} {V}_{N + {M}_{1}} \} , \\ \{ {K}_{N + 1} \text{:} {V}_{N + {1}_{2}} , {K}_{N + 2} \text{:} {V}_{N + {2}_{2}} , … , {K}_{N + M} \text{:} {V}_{N + {M}_{2}} \} , \\ … \\ \{ {K}_{N + 1} \text{:} {V}_{N + {1}_{L}} , {K}_{N + 2} \text{:} {V}_{N + {2}_{L}} , … , {K}_{N + M} \text{:} {V}_{N + {M}_{L}} \} ,\end{matrix} ] \} \}$$

Here the components of the JSON array are streamed asynchronously.

In one possible embodiment variant, a procedure for implementing the bracketing out can be embodied as follows. The following procedure functions for both sensor data and event data:

| | |
|---|---|
| obj.get( ); | // all data from the source are read into the object. |
| constObj = newObj( ); | // ... obtains the constant portions of the object |
| varObj = newObj( ); | // ... obtains the variable portions of the object. |
| for all ( pair ϵobj ) { | |

| | |
|---|---|
| if ( pair.value.isVariable( ) ) { | // decomposition of the object |
| into ... | |

| | |
|---|---|
| varObj.add( pair.key, pair.value ); | // ... variable and ... |
| } else { | |

| | |
|---|---|
| constObj.add( pair.key, pair.value ); | // ... constant portions |
| } | |
| } | |

| | |
|---|---|
| stream.send( constObj ); | // the constant portion of the object is transmitted |
| stream.send( “[” ); | // the array is opened for streaming |
| stream.send( varObj ); | // the variable portion of the object is transmitted |
| while ( TRUE ) { | |
| obj.get( ) | // reading in the next object. |
| for all ( pair ϵobj ) { | |

```
        if ( pair.value.isVariable( ) } { // filtering of the variable portions
      }
      stream.send( varObj ); //
            varObj.add( pair.key, pair.value );
```

| | |
|---|---|
| } | only the variable portion of the |
| object is transmitted | |
| } | |

| | |
|---|---|
| stream.send( “]” ); | // merely for the sake of completeness |

This procedure involves determining which portions of the data object are deemed to be constant, and which are deemed to be variable. In one possible embodiment, the evaluation is carried out during the run time. Alternatively, it may also not be at the run time when the data evaluation is carried out.

On the part of the receiver, the processing is effected in the reverse order. Each received data object can be updated by the next data object and be completed for further data processing.

If no streaming mechanism is available in the system, it is likewise possible to carry out the data reduction or data compression in accordance with the method according to the embodiments of the invention. In this case, with respect to the variable portion of the data object, a unique identification identifier is sent as well, on the basis of which the variable object portions can be assigned again to the object portion having the constant attributes:

$${\{}^{″} Event {data}^{″} \text{:} \{ EventID : eventID , {K}_{1} \text{:} {C}_{1} , {K}_{2} \text{:} {C}_{2} , … , {K}_{N} \text{:} {C}_{N} , {K}_{N + 1} \text{:} {V}_{N + {1}_{1}} , {K}_{N + 2} \text{:} {V}_{N + {2}_{1}} , … , {K}_{N + M} \text{:} {V}_{N + {M}_{1}} \} \} \\ {\{}^{″} Event {data}^{″} \text{:} \{ EventID \text{:} eventID , {K}_{1} \text{:} {C}_{1} , {K}_{2} \text{:} {C}_{2} , … , {K}_{N} \text{:} {C}_{N} , {K}_{N + 1} \text{:} {{V}_{N + 1}}_{2} , {K}_{N + 2} \text{:} {V}_{N + {2}_{2}} , … , {K}_{N + M} \text{:} {V}_{N + {M}_{2}} \} \} \\ … \\ {\{}^{″} Event {data}^{″} \text{:} \{ EventID \text{:} eventID , {K}_{1} \text{:} {C}_{1} , {K}_{2} \text{:} {C}_{2} , … , {K}_{N} \text{:} {C}_{N} , {K}_{N + 1} \text{:} {V}_{N + {1}_{L}} , {K}_{N + {1}_{L}} , {K}_{N + 2} \text{:} {V}_{N + {2}_{L}} , … , {K}_{N + M} \text{:} {V}_{N + {M}_{L}} \} \}$$

In this case, Kₛ denotes the keys, Cₛ denotes constant values, and Vₛ denotes variable values.

This can be summarized as follows:

$${\{}^{″} Event {data}^{″} : \{ EventID : eventID , {K}_{1} \text{:} {C}_{1} , {K}_{2} \text{:} {C}_{2} , … , {K}_{N} \text{:} {C}_{N} \} \} \\ {\{}^{″} Event {data}^{″} \text{:} \{ EventID \text{:} eventID , {K}_{N + 1} \text{:} {V}_{N + {1}_{1}} , {K}_{N + 2} \text{:} {V}_{N + {2}_{1}} , … , {K}_{N + M} \text{:} {V}_{N + {M}_{1}} \} \} \\ {\{}^{″} Event {data}^{″} \text{:} \{ EventID \text{:} eventID , {K}_{N + 1} \text{:} {V}_{N + {1}_{2}} , {K}_{N + 2} \text{:} {V}_{N + {2}_{2}} , … , {K}_{N + M} \text{:} {V}_{N + {M}_{2}} \} \} \\ … \\ {\{}^{″} Event {data}^{″} \text{:} \{ EventID \text{:} eventID , {K}_{N + 1} \text{:} {V}_{N + {1}_{L}} , {K}_{N + 2} \text{:} {V}_{N + {2}_{L}} , … , {K}_{N + M} \text{:} {V}_{N + {M}_{L}} \} \}$$

The complete data sets can thus be reconstructed again as far as necessary on the part of the receiver 5 on the basis of the identification identifier.

Streaming of the variable portions of discrete data objects can thus be carried out. In some cases, however, it is not known which portions of a data object are variable portions and which are constant portions or when the variable portions change and when not. In these cases, a differentiation can be carried out dynamically. The transmission of time stamps (Timestamp) at intervals of 1.5 seconds is represented below as an example. The construct is given as follows:

```
{ “Timestamp” :
    { “Year” : number ,
      “Month” : number ,
      “Day” : number ,
      “Hour” : number ,
      “Minute” : number ,
      “Second” : number ,
      “Millisecond” : number } }
```

In the example illustrated, all of the components of the object are variable, albeit not always. One specific point in time is for example:

```
{ “Timestamp” :
    { “Year” : 2016 ,
      “Month” : 7 ,
      “Day” : 29 ,
      “Hour” : 1 ,
      “Minute” : 23 ,
      “Second” : 45
      “Millisecond” : 678,01 } }
```

In order to represent the time stamp one and a half seconds later, it suffices to update only the seconds and milliseconds:

```
{ “Timestamp” :
    { “Second” : 47 ,
      “Millisecond” : 178,01 } }
```

One hour later it is necessary merely to transmit the following data object if no further transmissions have taken place in the interim:

{ “Timestamp” :
{ “Hour” : 2 } }

As can be discerned from the example above, the method according to the embodiments of the invention and the compression device according to the embodiments of the invention offer a considerable potential for data reduction.

For the case where only a few changes are present even in the variable portion of a data object, in one possible embodiment it is possible to transmit only these changes. A procedure in which this is implemented may read as follows:

| | |
|---|---|
| obj.get( ); | // data from the source are read into the object |
| refObj = obj; | // creates a copy as reference object |
| send( obj ); | // complete transmission of the data object |
| while ( TRUE ) { | |
| obj.get( ); | |

| | |
|---|---|
| newObj = reduce( obj, refObj ); | // construction of a reduced copy of obj |

| | |
|---|---|
| newObj.add( “EventID”, obj.getValue( “Event.ID” ) }; | // for recovery |

| | |
|---|---|
| refObj = obj; | // object becomes reference object |
| send( newObj ); | // transmission of the reduced data object |
| } | |

The reduced function specified in the above procedure implements the following table for each key-value pair of the data object. It is assumed here that the JSON data objects obj and refObj differ only in the values, but not in the keys. The reduction can be extended to a JSON array by virtue of only the differing components of the array being transmitted.

| | Key | Value | reduced result → newObj |
|---|---|---|---|
| obj | K | V1 = { k1 : v1 , k2 : | return |
| | | v2 , . . . , kn : vn } | |
| refObj | K | V2 = { k1 : w1 , k2 : | “{” ° |
| | | w2 , . . . , kn : wn } | ( if (v1 ≠ w1 ) “k1 : v1” ) ° |
| | | | ( if ( v2 ≠ w2 ) “, k2 : v2” ) ° |
| | | | . . . |
| | | | ( if ( vn ≠ wn ) “, kn : vn” ) ° |
| | | | “}” |
| obj | K | V1 = { v1 , | return |
| | | v2 , . . . , vn } | |
| refObj | K | V2 = { w1 , | “[” ° |
| | | w2 , . . . , wn } | ( if (v1 ≠ w1 ) “v1” ) ° “,” ° |
| | | | ( if ( v2 ≠ w2 ) “v2” ) ° “,” ° |
| | | | . . . |
| | | | ( if ( vn ≠ wn ) “vn” ) ° |
| | | | “]” |

In the case of reducing a data object, an empty data object “{ }” can be transmitted in the simplest case. An empty data object is permissible according to the JSON definition.

In the case of reducing an array, the result may deviate from the JSON definition since a comma is always transmitted, even if components are missing on account of equality. In the extreme case that may appear as follows:

“[ ,, . . . ,]”.

A construct of this type is not provided in the conventional JSON definition, but during the reconstruction of an array may help in finding the correct place for the changed value, for example in an array the third component: “[ ,,w, . . . ]”.

The reception on the part of the receiver 5 takes place in the reverse order. Each received data object is updated by the next data object and completed and processed further internally.

In one possible embodiment, an extension is possible in the case of recursive data structures. In the case of a recursive structure of the values of the data objects or arrays, the reduction can also be applied to the values. In the case of objects, the above table can be extended as follows:

. . . (if (vi !=wi) “ki: “*reduce(vi)*”,”) * . . . .

In the case of arrays, the table can be extended in a manner as represented as follows:

. . . (if(vi !=wi) reduce(vi)) * . . . .

The reduction of atomic values, such as, for example, a character string or strings, numerical values, or Boolean values, is the values themselves. The recursion can be anchored as a result.

In a further possible embodiment of the method according to the embodiments of the invention, it is possible to carry out an extension with respect to the reference object. In one possible embodiment variant, the transmission of structured data or data objects is realized in the sense that each data object is utilized as reference object, and so only the changes with respect thereto have to be transmitted. In an alternative embodiment variant deviating therefrom, a reference object can be given a longer endurance. Depending on the application or configuration, every 10^{th}, 20^{th} or for example 100^{th} data object can be declared as a reference object by means of the transmission cycles being counted as well. Instead of the line:

refObj=obj; object becomes reference object

the following lines can be used in the procedure represented above:

| | |
|---|---|
| if ( count++ >= N ) { | // N denotes endurance in transmission cycles |
| refObj = obj; | // object becomes reference object |
| count = 0; | |
| } | |

In an alternative embodiment, a temporal endurance can also be taken into account or defined as a replacement for the number of transmission cycles by means of the counter being replaced by a point in time, as follows:

```
  if ( getTime( ) >= nextTime ) {
// nextTime denotes the point in time for the transmission of the
next reference object.
    refObj = obj;
    nextTime = getTime( ) + deltaT;
  // deltaT denotes the endurance of the reference object.
```

On the part of the receiver 5 there must be clarity in respect of which data object is a reference object. Therefore, corresponding information is preferably communicated, e.g. a further attribute, which can be set whenever the corresponding condition is met:

```
    if ( count++ >= N ) {
// or if ( getTime( ) >= nextTime ) {
        ...
        newObj.add( “isRefObj”, true };
    }
    send( newObj };
```

On the part of the receiver 5, the reference object is selected and updated with the subsequent received objects and completed in order afterward to be able to carry out the data processing. The reference object is maintained until a new reference object is received by the receiver 5. For this purpose, the reference object is preferably stored in a buffer memory provided for this purpose.

The method according to the embodiments of the invention and the compression device according to the embodiments of the invention serve for the efficient data transmission of structured data or data objects. In this case, a lossless compression without loss of information is effected. In the method according to the embodiments of the invention, the constant portion of the structured data object is preferably transmitted only once and afterward the variable data object portions are transmitted separately. In one possible embodiment, at the run time it is possible to decide whether there has been a change in an object component in relation to a reference data object. In this case, only the changes are transmitted to the receiver 5. The method according to the embodiments of the invention also allows a data transmission without streaming.

Although the invention has been illustrated and described in greater detail with reference to the preferred exemplary embodiment, the invention is not limited to the examples disclosed, and further variations can be inferred by a person skilled in the art, without departing from the scope of protection of the invention.

For the sake of clarity, it is to be understood that the use of “a” or “an” throughout this application does not exclude a plurality, and “comprising” does not exclude other steps or elements.

1. A method for a lossless compression of a data stream having a sequence of structured data objects having a list of properties which each contain a key-value pair, the method comprising:
(a) decomposing the structured data objects of the data stream into a constant data object portion, which has key-value pairs having constant values, and into variable data object portions, which have key-value pairs having variable values;
(b) transmitting the constant data object portion of the structured data objects once to a receiver; and
(c) transmitting the variable data object portions of the decomposed data objects of the data stream to the receiver.

2. The method as claimed in claim 1, wherein the structured data objects of the data stream have JavaScript Object Notation, JSON, and data objects.

3. The method as claimed in claim 1, wherein each key-value pair has a key formed by a character string or a number.

4. The method as claimed in claim 1, wherein the key-value pair has a value formed by a data object, an array, a character string, a numerical value or a logical value.

5. The method as claimed in claim 1, wherein the variable data object portion of the decomposed structured data object of the data stream has an array, the components of which are key-value pairs that are streamed asynchronously to the receiver.

6. The method as claimed in claim 1, wherein the variable data object portions of a data stream each contain a unique identification identifier for identifying their association with the data stream.

7. The method as claimed in claim 1, wherein changes in the variable data object portion of the structured data object of the data stream relative to a reference data object are determined and transmitted to the receiver.

8. The method as claimed in claim 7, wherein the reference data object is formed by a structured data object of the data stream having a predetermined endurance.

9. The method as claimed in claim 7, wherein the reference data object of the data stream is identified as such and is transmitted to the receiver.

10. The method as claimed in claim 8, wherein the endurance of the reference data object is defined by a number of transmission cycles or a validity period.

11. The method as claimed in claim 1, wherein decomposing the structured data objects of the data stream is carried out at the run time during the transmission of the data stream to the receiver.

12. The method as claimed in claim 1, wherein, on the part of the receiver, the structured data objects of the data stream are reconstructed for further data processing on the basis of the obtained constant data object portion and the received variable data object portions.

13. The method as claimed in claim 1, wherein, on the part of the receiver, the structured data objects of the data stream are reconstructed for further data processing on the basis of the buffer-stored reference data objects and the received changes in the variable data object portions.

14. The method as claimed in claim 1, wherein the data stream is an event data stream, in particular a sensor data stream.

15. A compression device for a lossless compression of a data stream comprising a sequence of structured data objects having a list of properties which each consists of a key-value pair, wherein the device comprises:
(a) a data decomposition unit suitable for decomposing the structured data objects of the data stream into a constant data object portion, which has key-value pairs having constant values, and into variable data object portions, which have key-value pairs having variable values; and
(b) a data transmission unit, which transmits once the constant data object portion and separately the variable data object portions of the decomposed data objects to a receiver.
